(19) United States
(12) Patent Application Publication
(10) Pub. No.: US 2026/0002821 A1
(43) Pub. Date: Jan. 1, 2026

(54) Transistor IC Apparatus with Integrated Temperature Sensing

(71) Applicant: Texas Instruments Incorporated, Dallas, TX (US)

(72) Inventors: Zachary Lee, Santa Clara, CA (US); Vijay Reddy, Dallas, TX (US)

(21) Appl. No.: 18/759,941

(22) Filed: Jun. 30, 2024

(51) Int. Cl. G01K 7/01; H01L 23/34; H01L 29/06; H01L 29/40; H01L 29/66; H01L 29/78

(52) U.S. Cl. CPC G01K 7/015; H01L 23/34; H10D 30/0281; H10D 30/657; H10D 62/116; H10D 62/127; H10D 64/111

(57) ABSTRACT

The present disclosure introduces an IC apparatus that includes a transistor and circuitry, as well as method of manufacture of such IC apparatus. The transistor is constructed in layers formed in or over a semiconductor substrate and includes a polysilicon member proximate a feature of the transistor. The circuitry includes two connections to the polysilicon member and is configured to detect a temperature-dependent characteristic of the polysilicon member. The transistor may also or instead include oppositely doped portions of the semiconductor substrate, which form a junction diode. The circuitry may also or instead include connections to the oppositely doped substrate portions and may be configured to detect a temperature-dependent characteristic of the junction diode.

### BACKGROUND OF THE DISCLOSURE

Transistor arrays in an integrated circuit (IC), particularly high-power transistor arrays, are subject to high-temperature stresses that can cause damage. Thermal runaway due to FET self-heating is an example. On-chip temperature sensors are often used to prevent such high-temperature stress, such as in over-temperature protection circuits integrated with the transistors. However, such sensors add to the size and complexity of the transistors/arrays, thus increasing the cost and lowering the yield of such devices.

### SUMMARY OF THE DISCLOSURE

This summary is provided to introduce a selection of concepts that are further described below in the detailed description. This summary is not intended to identify indispensable features of the claimed subject matter, nor is it intended for use as an aid in limiting the scope of the claimed subject matter.

The present disclosure introduces an IC apparatus that includes a transistor and circuitry. The transistor is constructed in layers formed in or over a semiconductor substrate and includes a polysilicon member proximate a feature of the transistor. The circuitry includes two connections to the polysilicon member and is configured to detect a temperature-dependent characteristic of the polysilicon member.

The present disclosure also introduces a method of manufacturing an IC apparatus, including forming a transistor in layers formed in or over a semiconductor substrate and forming circuitry that includes two connections to the polysilicon member. Forming the transistor includes forming a polysilicon member proximate a feature of the transistor. The circuitry is configured to detect a temperature-dependent characteristic of the polysilicon member.

The present disclosure also introduces an IC apparatus that includes a transistor and circuitry. The transistor is constructed in layers formed in or over a semiconductor substrate, and includes oppositely doped portions of the semiconductor substrate that form a junction diode. The circuitry includes connections to the oppositely doped substrate portions and is configured to detect a temperature-dependent characteristic of the junction diode.

The present disclosure also introduces a method of manufacturing an IC apparatus, including forming a transistor in layers formed in or over a semiconductor substrate and forming circuitry. Forming the transistor includes forming oppositely doped portions of the semiconductor substrate that collectively form a junction diode. The circuitry includes connections to the oppositely doped substrate portions and is configured to detect a temperature-dependent characteristic of the junction diode.

These and additional aspects of the present disclosure are set forth in the description that follows, and/or may be learned by a person having ordinary skill in the art by reading the material herein and/or practicing the principles described herein. At least some aspects of the present disclosure may be achieved via means recited in the attached claims.

### BRIEF DESCRIPTION OF THE DRAWINGS

The present disclosure is understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a schematic sectional view of a portion of an example implementation of a transistor IC apparatus according to one or more aspects of the present disclosure.

FIG. 2 is a schematic sectional view of a portion of another example implementation of a transistor IC apparatus according to one or more aspects of the present disclosure.

FIG. 3 is a plan view of a portion of an example implementation of the transistor IC apparatus shown in FIGS. 1 and 2 according to one or more aspects of the present disclosure.

FIG. 4 is a plan view of a portion of another example implementation of the transistor IC apparatus shown in FIGS. 1 and 2 according to one or more aspects of the present disclosure.

FIG. 5 is a plan view of a portion of another example implementation of the transistor IC apparatus shown in FIGS. 1 and 2 according to one or more aspects of the present disclosure.

FIG. 6 is a plan view of a portion of another example implementation of the transistor IC apparatus shown in FIGS. 1 and 2 according to one or more aspects of the present disclosure.

FIG. 7 is a plan view of a portion of another example implementation of the transistor IC apparatus shown in FIGS. 1 and 2 according to one or more aspects of the present disclosure.

FIG. 8 is a plan view of a portion of another example implementation of the transistor IC apparatus shown in FIGS. 1 and 2 according to one or more aspects of the present disclosure.

FIG. 9 is a flow-chart of at least a portion of an example implementation of a method of manufacturing a transistor IC apparatus according to one or more aspects of the present disclosure.

FIG. 10 is a plan view of a portion of an example implementation of a transistor IC apparatus according to one or more aspects of the present disclosure.

FIG. 11 is a plot depicting electrical characteristics of the transistor IC apparatus shown in FIG. 10.

FIG. 12 is a flow-chart of at least a portion of another example implementation of a method of manufacturing a transistor IC apparatus according to one or more aspects of the present disclosure.

FIG. 13 is a plan view of a portion of an example implementation of the IC transistor IC apparatus shown in FIGS. 1 and 2 according to one or more aspects of the present disclosure.

FIG. 14 is a plan view of a portion of an example implementation of an IC transistor array according to one or more aspects of the present disclosure.

### DETAILED DESCRIPTION

The following disclosure is described with reference to the attached figures. The figures are not drawn to scale, and they are provided merely to illustrate the disclosure. Several aspects of the disclosure are described below with reference to example implementations for illustration. It should be understood that numerous specific details, relationships, and methods are set forth to provide an understanding of the disclosure. However, the following disclosure is not limited by the illustrated ordering of acts or events, some of which may occur in different orders and/or concurrently with other acts or events, yet still fall within the scope of the following disclosure. Moreover, not all illustrated acts or events are required to implement a methodology in accordance with the following disclosure.

In addition, although some of the embodiments illustrated herein are shown in two dimensional views with various regions having depth and width, it should be clearly understood that these regions are illustrations of only a portion of a device that is actually a three-dimensional structure. Accordingly, these regions will have three dimensions, including length, width, and depth, when fabricated on an actual device. Moreover, while the present disclosure illustrates by embodiments directed to example devices, it is not intended that these illustrations be a limitation on the scope or applicability of the various implementations. It is not intended that the example devices of the present disclosure be limited to the physical structures illustrated. These structures are included to demonstrate the utility and application of the present disclosure to example (and perhaps preferred) implementations.

It is also to be understood that the following disclosure may provide different examples for implementing different features of various implementations. Specific examples of components and arrangements are described below to simplify the present disclosure. These are, of course, merely examples and are not intended to be limiting. In addition, the following disclosure may repeat reference numerals and/or letters in more than one implementation. This repetition is for simplicity and clarity and does not in itself dictate a relationship between the various implementations and/or configurations discussed. Moreover, the formation of a first feature over or on a second feature in the description that follows may include implementations in which the first and second features are formed in direct contact and/or implementations in which additional features may be formed interposing the first and second features, such that the first and second features may not be in direct contact.

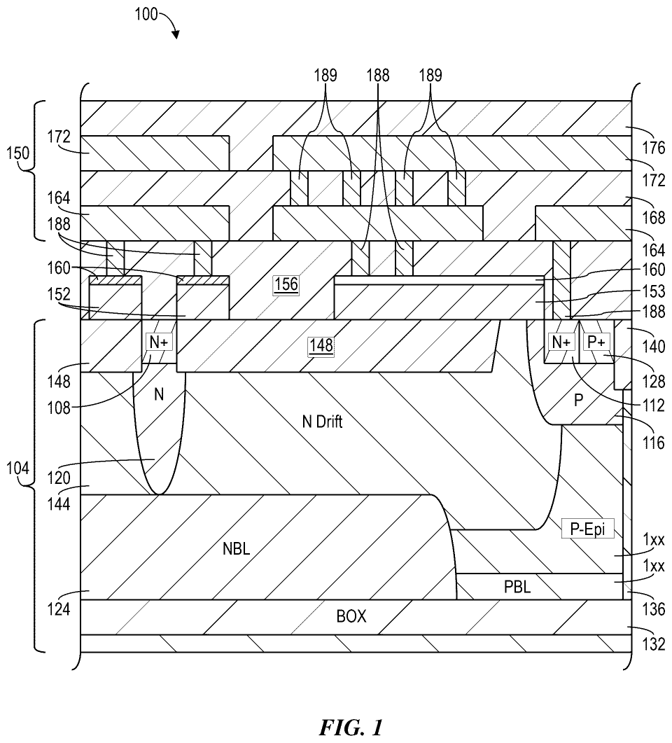

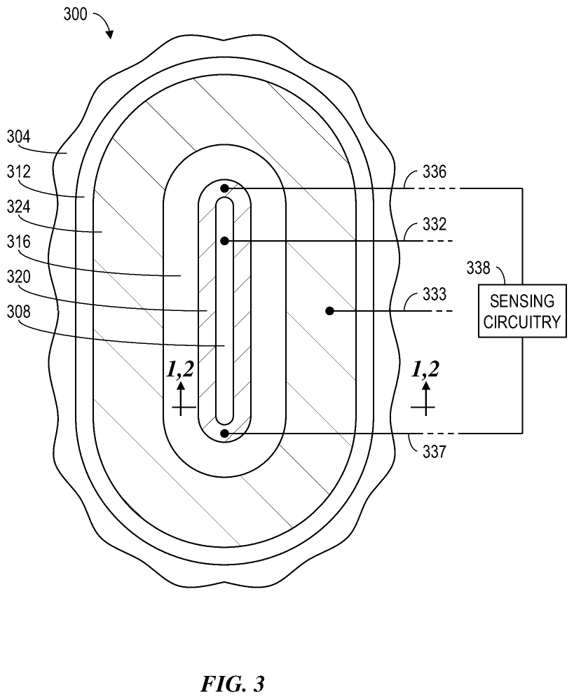

FIG. 1 is a schematic sectional view of a portion of an example implementation of an IC apparatus 100 according to one or more aspects of the present disclosure. The IC apparatus 100 includes a metal-oxide semiconductor (MOS) transistor constructed in a plurality of layers formed in and/or over a semiconductor substrate 104. The semiconductor substrate 104 may be formed from a p-doped semiconductor material (e.g., silicon, germanium, or gallium arsenide), and the transistor may be a laterally diffused MOS (LDMOS), such as may be utilized as a power transistor, having a drain 108 and a source 112 each formed by an n+ type implant in the substrate 104. Herein a “power transistor” is a transistor including a drain drift region, which may provide the ability of the transistor to sustain a large voltage drop from the source to the drain. The source 112 may be formed in a p-type well (DWELL) 116, and the drain 108 may be formed in an n-type well (NWELL) 120 extending into the substrate 104, such as to an n-type buried layer (NBL) 124. The drain 108 may have an elongated footprint, and the source 112 may be an elongated ring surrounding and laterally spaced from the drain 108 (e.g., as depicted in FIG. 3). A p+ type region 128 implanted in the DWELL 116 may form a backgate contact surrounding and abutting the source 112.

The transistor may be contained within an isolation tank formed by a buried oxide layer 132 and one or more dielectric-filled trenches 136 extending to the buried oxide layer 132 from one or more corresponding surface-penetrating isolation structures (e.g., shallow trench isolation (STI)) 140. An n-type implant may form a drain drift region 144 surrounding the drain 108 and having lateral boundaries underlying the DWELL 116. One or more additional surface-penetrating isolation structures (e.g., STI) 148 may surround the drain 108.

The IC apparatus 100 also comprises an interconnect structure 150 that may connect the transistor to other components and/or leads of the IC apparatus 100. For example, polysilicon members 152, 153 separated by portions of a pre-metal dielectric layer 156 are formed on the substrate 104 (perhaps with an intervening oxide layer, not shown). The polysilicon member 152 may form a drain field plate, and the polysilicon member 153 may form a gate/field plate. At least portions of one or more of the polysilicon members 152 may be silicided, thus being capped by portions of a silicide layer 160. In some examples a portion of the polysilicon member 152 or the polysilicon member 153 may include a silicide blocking layer, and may thus include a non-silicided portion.

A first metal interconnect layer may comprise copper, aluminum, and/or other metal traces 164 separated by portions of a first interlayer dielectric layer 168. A second metal interconnect layer may comprise copper, aluminum, and/or other metal traces 172 separated by portions of a second interlayer dielectric layer 176. Although not depicted in FIG. 1, the IC apparatus 100 may comprise additional metal interconnect layers. Contacts 188 interconnect one or more of the silicided portions of the polysilicon members 152, 153 (and perhaps the drain 108 and/or source 112, although not shown in FIG. 1) to one or more of the metal traces 164, and vias 189 interconnect one or more of the metal traces 164 to one or more of the metal traces 172.

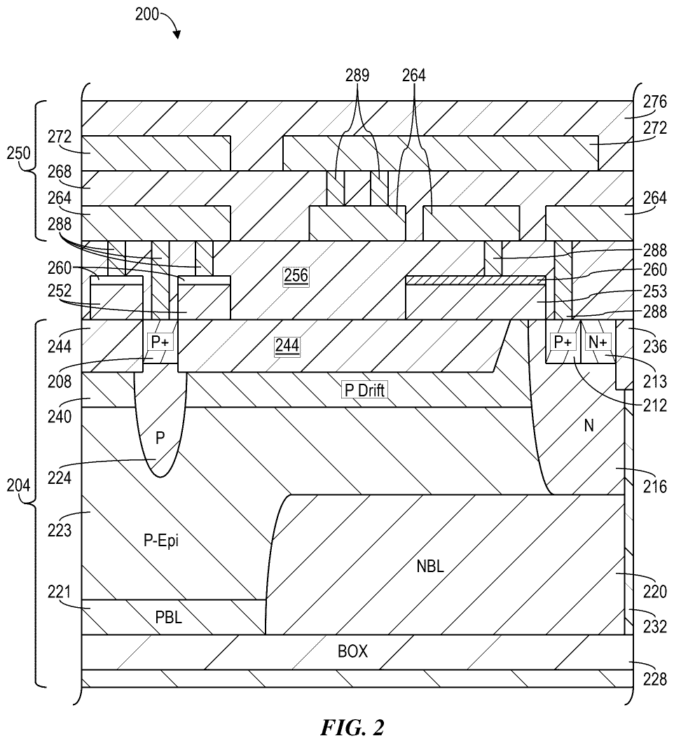

The present disclosure is also applicable to transistors other than the example LDMOS transistor depicted in FIG. 1. For example, FIG. 2 is a schematic sectional view of a portion of an example implementation of an IC apparatus 200 according to one or more aspects of the present disclosure, in which the transistor is a drain-extended MOS (DEMOS), specifically a p-channel DEMOS (DEPMOS) transistor (such as may be utilized as a power transistor), constructed in a plurality of layers formed in and/or over a semiconductor substrate 204. The semiconductor substrate 204 may be formed from a p-doped semiconductor material (e.g., silicon, germanium, or gallium arsenide). The DEPMOS transistor comprises a drain 208 and a source 212 each formed by a p+ type implant in the substrate 204.

The drain 208 may have an elongated footprint, and the source 212 may have an elongated, ring-shaped footprint surrounding and laterally spaced from the drain 208 (e.g., as depicted in FIG. 3). The source 212 may be formed in an NWELL 216, such as may have an elongated, ring-shaped footprint corresponding to that of the source 212, and that extends to (or toward) an NBL 220 implanted above a buried oxide (BOX) 228. An n+ type region 213 implanted in the NWELL 216 may form a backgate contact surrounding and abutting the source 212. The drain 208 may be formed in a p+ type well (PWELL) 224, such as may have an elongated footprint encompassing and/or otherwise corresponding to that of the drain 208, and that extends toward (or into) a p-type buried layer (PBL) 221. The PBL 221 extends within (and may abut) an inner perimeter of the NBL 220.

The DEPMOS transistor may be contained within an isolation tank formed by the BOX 228 and one or more dielectric-filled trenches 232 extending to the BOX 228 from one or more corresponding surface-penetrating isolation structures (e.g., STI) 236. A p-type implant (e.g., having a dopant concentration greater than that of the substrate 204 and/or an epitaxial p-type layer (P-Epi) 223) may form a drift region 240 surrounding the PWELL 224 and abutting an inner perimeter of the NWELL 216. One or more additional surface-penetrating isolation structures (e.g., STI) 244 may surround the drain 108.

The IC apparatus 200 also comprises an interconnect structure 250 that may connect the transistor to other components and/or leads of the IC apparatus 200. For example, polysilicon members 252, 253 separated by portions of a pre-metal dielectric layer 256 are formed on the substrate 204 (perhaps with an intervening oxide layer, not shown). The polysilicon member 252 may form a drain field plate, and the polysilicon member 253 may form a gate/field plate. At least portions of one or more of the polysilicon members 252, 253 may be silicided, thus being capped by portions of a silicide layer 260. In some examples a portion of the polysilicon member 252 or the polysilicon member 253 may include a silicide blocking layer, and may thus include a non-silicided portion.

A first metal interconnect layer may comprise copper, aluminum, and/or other metal traces 264 separated by portions of a first interlayer dielectric layer 268. A second metal interconnect layer may comprise copper, aluminum, and/or other metal traces 272 separated by portions of a second interlayer dielectric layer 276. Although not depicted in FIG. 2, the IC apparatus 200 may comprise additional metal interconnect layers. Contacts 288 interconnect one or more of the silicided portions of the polysilicon members 252, 253 (and perhaps the drain 208 and/or source 212) to one or more of the metal traces 264, and vias 289 interconnect one or more of the metal traces 264 to one or more of the metal traces 272.

The example implementations depicted in FIGS. 1 and 2 include n-type source and drain (in LDMOS or n-channel DEMOS (DENMOS)) or p-type source and drain (in DEPMOS) formed over a p-type substrate. However, other implementations within the scope of the present disclosure may include other doping schemes, such as p-type sources and drains formed in an n-type substrate, among other examples. Moreover, one or more aspects of the present disclosure may be applicable or readily adaptable to IC apparatus having transistors other than the LDMOS transistor depicted in FIG. 1 and the DEMOS transistor depicted in FIG. 2, including other silicon-on-insulator (SOI) transistors (e.g., high-power transistors) and/or other transistors for which a temperature-dependent characteristic may be monitored utilizing existing transistor manufacturing processing.

FIG. 3 is a plan view of a portion of an example implementation of an IC apparatus 300 according to one or more aspects of the present disclosure. The IC apparatus 300 may have one or more aspects and/or features of the IC apparatus 100, 200 shown in FIGS. 1 and 2. For example, the IC apparatus 300 may comprise an LDMOS, DEMOS, or other SOI transistor, such as may be utilized as a power transistor. The sectional views depicted in FIGS. 1 and 2 may be taken along the section lines “1,2” shown in FIG. 3. However, the hatching in FIG. 3 does not indicate a sectional view, but instead distinguishes various polysilicon features to provide clarity of view and case of understanding.

The plan view of the IC apparatus 300 depicts an example layout of features formed in a semiconductor substrate 304, such as a drain 308, a source 312, and an STI 316, as well as polysilicon members formed over the substrate 304, such as a drain field plate 320 and a gate/field plate 324. The substrate 304, drain 308, source 312, and STI 316 may have one or more aspects in common with and/or otherwise be similar to, respectively, one or both of the substrates 104, 204, one or both of the drains 108, 208, one or both of the sources 112, 212, and one or both of the isolation structures 148, 244 depicted in FIGS. 1 and/or 2. Likewise, the drain field plate 320 and gate/field plate 324 may have one or more aspects in common with and/or otherwise be similar to, respectively, one or both of the drain field plates 152, 252 and one or both of the gate/field plates 153, 253 depicted in FIGS. 1 and/or 2. In the example implementation depicted in FIG. 3, the drain 308 is an elongated feature (i.e., being multiple times longer than wide), and the drain field plate 320 has a layout that, if projected toward the substrate 304 (i.e., into the page in FIG. 3), surrounds at least a central portion of the underlying drain 308. The gate/field plate 324 surrounds but is spaced apart from the drain field plate 320, such that at least a portion of the STI 316 is visible between the drain and gate/field plates 320, 324 in the example view depicted in FIG. 3. Similar spacing of the corresponding features can be seen in the related examples depicted in FIGS. 1 and 2. However, layouts other than as depicted in FIGS. 1-3 are also within the scope of the present disclosure.

The present disclosure introduces detecting the temperature or a temperature-dependent characteristic of at least one of the polysilicon members 320, 324 and/or another transistor feature proximate one of the polysilicon members 320, 324. For example, the resistance of polysilicon is related to temperature by a temperature coefficient of resistivity, such that a detected resistance of a polysilicon member can be utilized to determine the temperature of the polysilicon member. Other temperature-dependent characteristics of the polysilicon member (current, conductivity, elongation, etc.) may also or instead be detected and utilized to determine the temperature of the polysilicon member. Moreover, the temperature of the polysilicon member determined from the detected resistance or other temperature-dependent characteristic may also be utilized to determine the temperature of the source, drain, and/or other transistor feature proximate the temperature-monitored polysilicon member. For example, the temperature of the drain field plate 320 may be utilized to determine the temperature of or near the underlying drain 308, whereas the temperature of the gate/field plate 324 may be utilized to determine the temperature of or near the underlying source 312 or channel region (not shown).

Accordingly, in addition to a drain bias 332, a gate drive 333, and/or other operational connections to the IC apparatus 300, as depicted in FIG. 3, the IC apparatus 300 may also comprise at least two connections 336, 337 between at least one of the polysilicon members and sensing circuitry 338 for detecting the temperature of the polysilicon member connected by the connections 336, 337. In the example shown in FIG. 3, the connections 336, 337 connect the sensing circuitry 338 to opposite ends of the drain field plate 320 so as to determine the temperature of the drain field plate 320, which can then be utilized to determine the temperature of the proximate drain 308. However, other features of the IC apparatus 300 may instead (or also) be monitored by utilizing the sensing circuitry 338 to detect the temperature of polysilicon members other than the drain field plate 320.

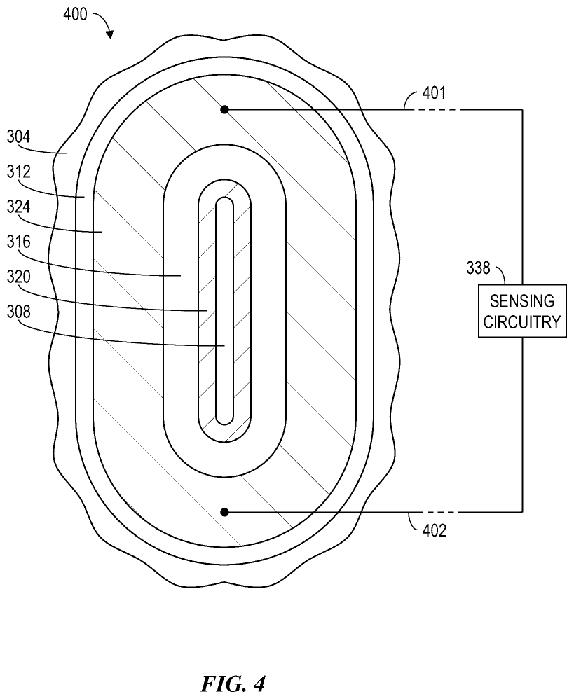

For example, another example implementation of the IC apparatus 300 is shown in FIG. 4, as designated by reference number 400. The IC apparatus 400 of FIG. 4 is analogous to the IC apparatus 300 of FIG. 3 except as described below. That is, instead of the temperature sensing connections 336, 337 connecting the drain field plate 320 to the sensing circuitry 338, the IC apparatus 400 shown in FIG. 4 includes temperature sensing connections 401, 402 connecting the sensing circuitry 338 to opposite ends of the gate/field plate 324. Accordingly, the sensing circuitry 338 can be utilized to measure the temperature of the gate/field plate 324. Moreover, the detected temperature of the gate/field plate 324 may be utilized to determine the temperature of the underlying source 312 and/or channel region (not shown), such that the sensing circuitry 338 may also be utilized to monitor (at least indirectly) the temperature of the source 312 and/or channel region.

In the example implementations depicted in FIGS. 3 and 4 and/or otherwise described above, the temperature detection can be performed without adding processing steps to the manufacture of the respective IC apparatus 300, 400. That is, an existing IC apparatus comprising an LDMOS, DEMOS, and/or other transistor can be modified by simply adding two or more connections (e.g., 336 and 337 or 401 and 402) to existing polysilicon members of the transistor. Such connections may be added to an existing connection manufacturing process (e.g., as traces in one or more of the metal layers of the interconnect structure 150, 250 shown in FIGS. 1 and 2). Thus, the temperature detection/monitoring introduced in the present disclosure can be implemented into existing manufacturing processes with little cost and impact on complexity and product yield.

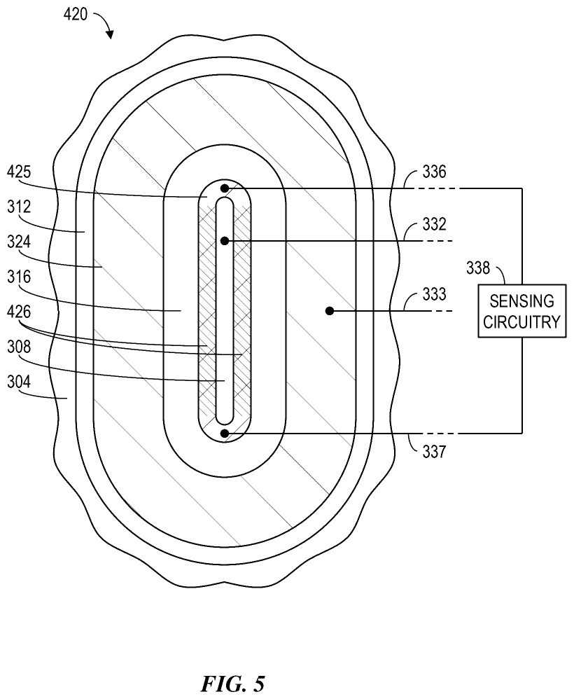

Additional small changes to an existing manufacturing process, however, may increase the effectiveness of the temperature detection/monitoring introduced in the present disclosure. For example, as described above with respect to FIGS. 1 and 2, the polysilicon members 152, 153, 252, 253 may be silicided, thus having corresponding portions of the respective silicide layer 160, 260 thereon. However, as also described above, portions of one or more of the polysilicon members 152, 153, 252, 253 may not be silicided, such as via the use of a silicide block during the silicide process. This concept is depicted in FIG. 5, which is a plan view of an IC apparatus 420 that is analogous to the IC apparatus 300 of FIG. 3 except as described below. That is, the IC apparatus 420 includes a drain field plate 425 that is analogous to the drain field plate 320 shown in FIG. 3, except that portions 426 (depicted by cross-hatching) are non-silicided. The non-silicided portions 426 of the drain field plate 425 increase the temperature coefficient of resistivity of the drain field plate 425, relative to the entire drain field plate 425 being silicided (e.g., as with the drain field plate 320 shown in FIG. 3). Accordingly, the range and/or accuracy of the temperature detection of the partially non-silicided drain field plate 425 is significantly higher than that of the fully silicided drain field plate 320. For example, the temperature coefficient of resistivity of the partially non-silicided drain field plate 425 may be a few thousand parts per million per degrees Kelvin (ppm/K), whereas the temperature coefficient of resistivity of the fully silicided drain field plate 320 may be less than one ppm/K. Accordingly, the significantly increased temperature coefficient of resistivity of the partially non-silicided drain field plate 425 may have a significantly higher sensitivity, accuracy, and/or resolution of temperature measurement (e.g., a resolution of tenths of degrees compared to tens of degrees).

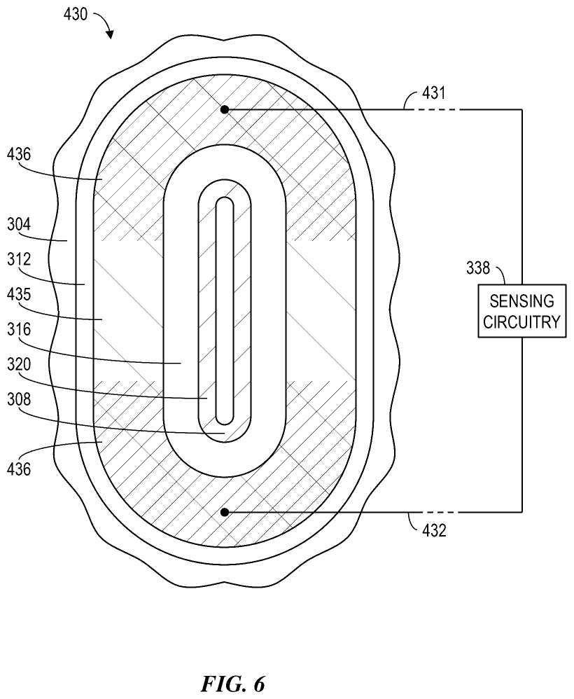

Another small change to an existing manufacturing process that may also increase the effectiveness of the temperature detection/monitoring introduced in the present disclosure entails altering the dopant profile of a polysilicon member connected to the sensing circuitry. This concept is depicted in FIG. 6, which is a plan view of an IC apparatus 430 that is similar to the IC apparatus 410 of FIG. 4 except as described below. That is, the IC apparatus 430 comprises a gate/field plate 435 that is analogous to the gate/field plate 324 shown in FIG. 4, except that at least portions 436 (depicted by cross-hatching) are implanted with a dopant to a different concentration than a remainder of the gate/field plate 435 (which may or may not be doped). In the example implementation depicted in FIG. 6, the doped portions 436 of the gate/field plate 435 comprise about 75% of the gate/field plate 435, although in other implementations within the scope of the present disclosure the doped portions 436 of the gate/field plate 435 may comprise 50-100% of the gate/field plate 435.

The doped portions 436 of the gate/field plate 435 may increase the temperature coefficient of resistivity of the backgate field plate 435. Accordingly, the range and/or accuracy of the temperature detection of the at least partially doped gate/field plate 435 is significantly higher than without the altered doping. For example, the temperature coefficient of resistivity of the at least partially doped gate/field plate 435 may be thousands of ppm/K, whereas the temperature coefficient of resistivity of the gate/field plate 435 without altered doping may be a few hundred ppm/K. Accordingly, the significantly increased temperature coefficient of resistivity of the at least partially doped gate/field plate 435 may have a significantly larger higher sensitivity, accuracy, or resolution of temperature measurement (e.g., accuracy of one degree compared to tens of degrees).

The doped portions 436 of the gate/field plate 435 may also be non-silicided, similar to the non-silicided portions 426 of the drain field plate 425 shown in FIG. 5. By combining the altered doping profile and non-silicided portions of the gate/field plate 435, the temperature coefficient of resistivity of the gate/field plate 435 may be increased from a range of 200-300 ppm/K to a range of 2,000-3,000 ppm/K. Similar improvement can be obtained by combining the altered doping profile and non-silicided portions of the drain field plate 320 in implementations utilizing the drain field plate 320 instead of (or in addition to) the gate/field plate 435 for temperature measurement.

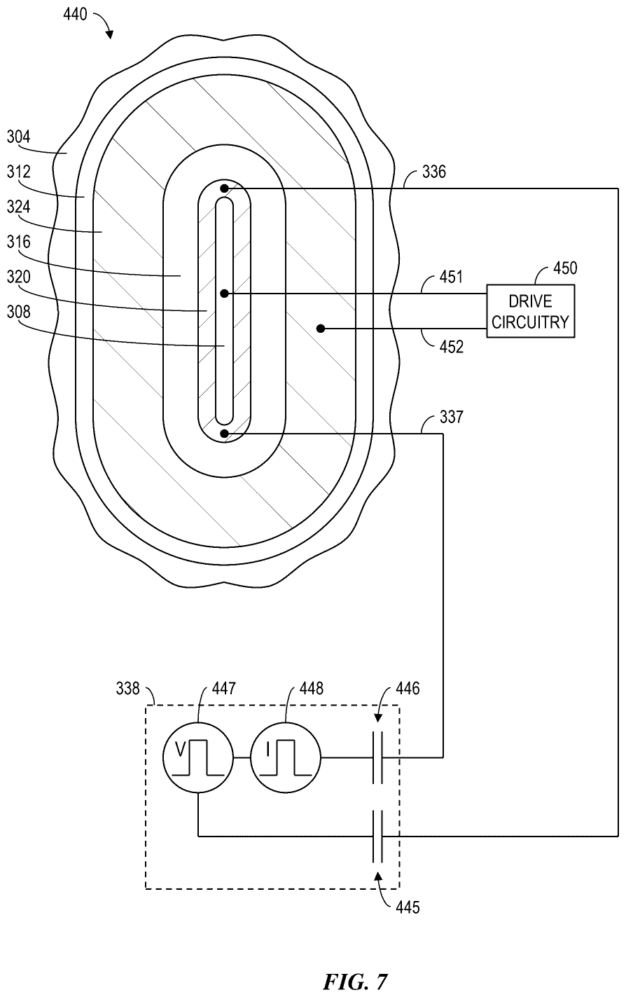

In the example implementations depicted in FIGS. 3-6 and/or otherwise described above, the sensing circuitry 338 may be included in or separate from the IC apparatus 300, 400, 420, 430. For example, FIG. 7 is a schematic view depicting the sensing circuitry 338 being separate from an IC apparatus 440. The IC apparatus 440 is analogous to the IC apparatus 300 except as described below.

In the example implementation depicted in FIG. 7, the sensing circuitry 338 is capacitively coupled to the temperature-sensing connections 336, 337, such as via respective capacitive elements 445, 446. The example sensing circuitry 338 includes a voltage source 447 and an current sensor 448, such that the sensing circuitry 338 can be utilized to determine the temperature-dependent resistivity of the drain field plate 320 based on, for example, a pulse voltage from the voltage source 447 applied to the drain field plate 320 via the connections 336, 337 and a resulting pulse current detected by the current sensor 448. However, other circuit designs within the scope of the present disclosure may be utilized for detecting the temperature of the drain field plate 320 and/or other polysilicon member, including based on temperature-dependent characteristics other than resistivity. For example, instead of the current sensor 448 being utilized to detect a current resulting from a voltage signal from the voltage source 447, a voltage sensor may be utilized to detect a voltage resulting from a current applied to the drain field plate 320 (and/or other polysilicon member).

The example implementation shown in FIG. 7 also depicts drive circuitry 450 connected to a drain bias connection 451, a gate drive connection 452, and/or other operational connections to the IC apparatus 440. As with the sensing circuitry 338, the drive circuitry 450 may be included in or separate from the IC apparatus 440.

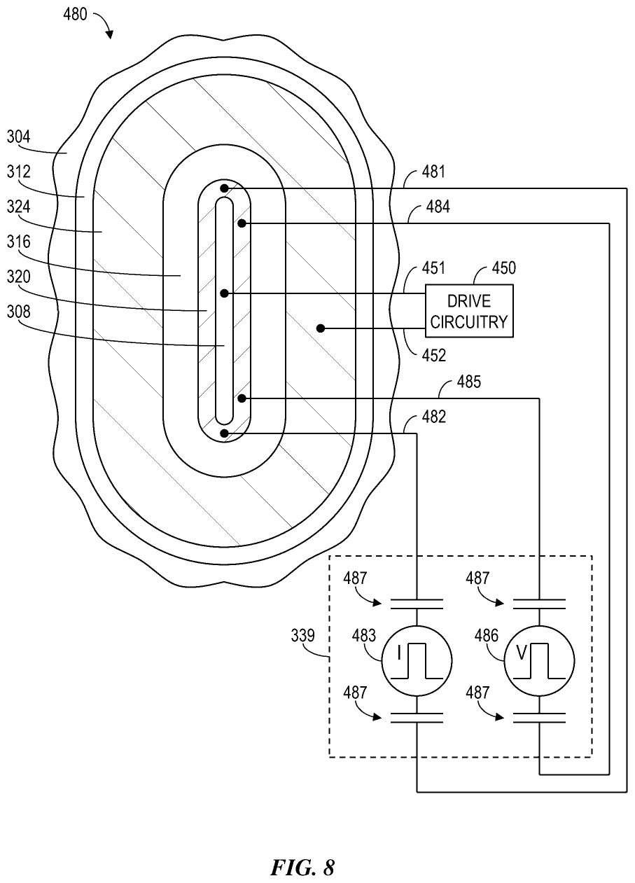

FIG. 8 is a schematic view of another example implementation of the IC apparatus 440 shown in FIG. 7 and designated in FIG. 8 by reference number 480. The IC apparatus 480 is analogous to the IC apparatus 440 except as described below.

That is, the sensing circuitry 338 depicted in FIG. 7 includes two connections 336, 337 to the drain field plate 320, such as for sending a current pulse to the drain field plate 320 and detecting a resulting voltage pulse, or for sending a voltage pulse to the drain field plate 320 and detecting a resulting current pulse. However, the sensing circuitry 339 depicted in FIG. 8 includes two connections 481, 482 for sending a current pulse from a current source 483 to the drain field plate 320, and two connections 484, 485 for detecting a resulting voltage pulse from the drain field plate 320 via a voltage sensor 486. The reverse of this arrangement may also be utilized, in which the voltage meter 486 may be a voltage source for sending a voltage pulse to the drain field 320 via the connections 484, 485 and the current source 483 may be an current sensor for detecting a resulting current pulse from the drain field plate 320 via the connections 481, 482. Either arrangement may be a Kelvin connection, as known to a person of ordinary skill in the art (such that the arrangements depicted in FIG. 7 and described in the accompanying text may be referred to as a non-Kelvin connection). As also depicted in FIG. 8, the voltage/current sources/detectors 483, 486 and/or other components of the sensing circuitry 339 may be capacitively coupled to the corresponding connections 481, 482, 484, 485, such as by one or more capacitive elements 487.

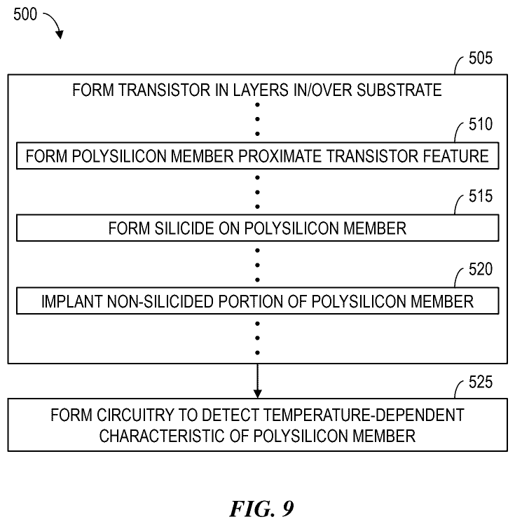

FIG. 9 is a flow-chart diagram of a portion of an example implementation of a method 500 of manufacturing an IC apparatus according to one or more aspects of the present disclosure. The method 500 may be utilized in the manufacturing of the IC apparatus 300, 400, 420, 430, and/or 440 shown in FIGS. 3-8.

The method 500 includes forming 505 a transistor in a plurality of layers formed in or over a semiconductor substrate, including forming 510 a polysilicon member proximate a feature of the transistor. As described above, forming 505 the transistor may comprise forming 515 silicide on a portion of the polysilicon member, thus defining silicided and non-silicided portions of the polysilicon member. As also described above, forming 510 the polysilicon member may comprise implanting 520 the non-silicided portion with a dopant such that a temperature coefficient of resistivity of the non-silicided portion is greater than a temperature coefficient of resistivity of the silicided portion. The method 500 also includes forming 525 circuitry comprising two or more connections (e.g., a Kelvin connection) to the polysilicon member, wherein the circuitry is configured to detect a temperature-dependent characteristic of the polysilicon member.

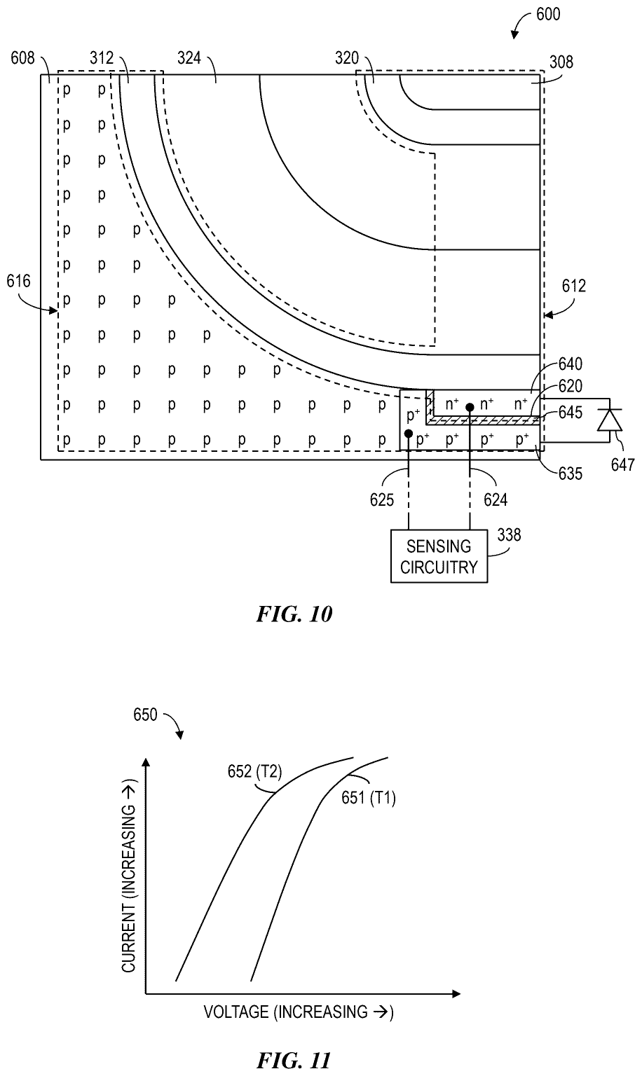

The present disclosure also introduces utilizing transistor features other than (or in addition to) polysilicon members to detect a temperature-dependent characteristic of the transistor. For example, FIG. 10 is a plan view of a portion of an IC apparatus 600 having a transistor comprising polysilicon members formed over a semiconductor substrate 608, for example analogous to the transistors of FIGS. 1 and 3. For example, the semiconductor substrate 608 may include the above-described drain 308 and source 312, and the polysilicon members may include the above-described drain field plate 320 and gate/field plate 324.

The semiconductor substrate 608 comprises various n-doped regions 612, including the drain 308 and the source 312, and p-doped region 616 analogous to the DWELL 116 (backgate or body region), which may be existing features of current IC designs. Some or all of the p-doped region 616 may include a p⁺ contact region over a p-type well such as the DWELL 116. In one example, a p⁺ backgate contact 635 to an underlying p-well is representative of any of many possible connections to the p-well, and an n⁺ source contact 640 is representative of any of various possible connections to the source 312. Unlike the examples of FIGS. 1 and 3, however, the IC apparatus 600 includes a silicide-free region (denoted by hatching) 645 between the backgate contact 635 and the source contact 640, so the transistor does not have an integrated backgate. The silicide-free region 645 may be implemented, for example, by an STI feature or a silicide blocking feature. Thus, a diode 647 is formed at the p-n junction between the source contact 640 and the underlying p-well, represented by boundary 620. By adding connections 624, 625 to the manufacturing process, similar to the above-described addition of the polysilicon temperature sensing connections (336, 337, 401, 402, 431, 432, 481, 482, 484, 485 in FIGS. 3-8), the temperature at the location of the p-n junction can be detected based on the I-V characteristic of the junction diode. In implementations, it may be preferable that the transistor be inactive when measuring the I-V characteristic of the diode 647.

In the example implementation shown in FIG. 10, the sensing circuitry 338 is configured to detect a temperature-dependent characteristic at the boundary 620. For example, the sensing circuitry may be configured to detect the current and/or voltage across the junction diode, which is indicative of the temperature at the boundary 620. As described above, the sensing circuitry 338 may be included in or separate from the IC apparatus 600. Thus, the IC apparatus 600 is an example implementation in which the junction diode 647 can also be used as a temperature sensor.

The temperature at the junction may be determined from a lookup table and/or other empirical data. For example, FIG. 11 is a plot 650 depicting a first current-voltage (I-V) characteristic 651 of an example junction diode (e.g., the junction diode of the IC apparatus 600 depicted in FIG. 10) at a temperature T1 and a second I-V characteristic 652 of the example junction diode at a higher temperature T2. Such characteristics 651, 652 may be determined empirically for a range of temperatures encompassing the expected temperatures during both normal and abnormal operation of the IC apparatus, which may then be utilized in monitoring production IC apparatus. (Similar empirical data techniques may be utilized for the implementations depicted in FIGS. 3-8.)

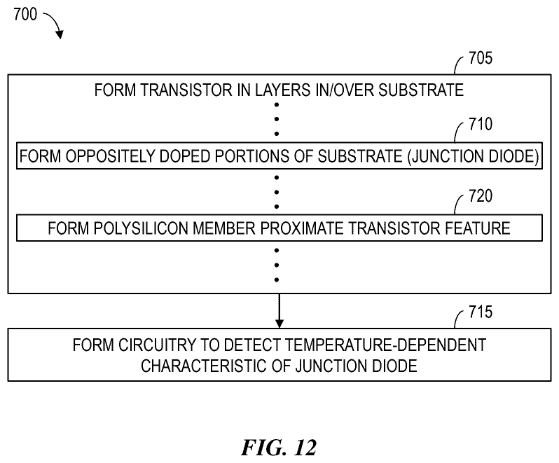

FIG. 12 is a flow-chart diagram of a portion of an example implementation of a method 700 of manufacturing an IC apparatus according to one or more aspects of the present disclosure. The method may be utilized in the manufacturing of the IC apparatus 600 shown in FIG. 10.

The method 700 includes forming 705 a transistor in a plurality of layers formed in or over a semiconductor substrate, including forming 710 oppositely doped portions of the semiconductor substrate that collectively form a junction diode. The method 700 also includes forming 715 circuitry comprising connections to the oppositely doped substrate portions, the circuitry being configured to detect a temperature-dependent characteristic of the junction diode. As described above, the temperature-dependent characteristic may be current resulting from a voltage applied across the junction diode, that current (and corresponding voltage) being indicative of a temperature of the junction diode.

Forming 705 the transistor may also include forming 720 a polysilicon member proximate a channel, source, drain, and/or other feature of the transistor. In such implementations, the circuitry may also comprise connections to the polysilicon member and may be configured to detect a temperature-dependent characteristic of the feature.

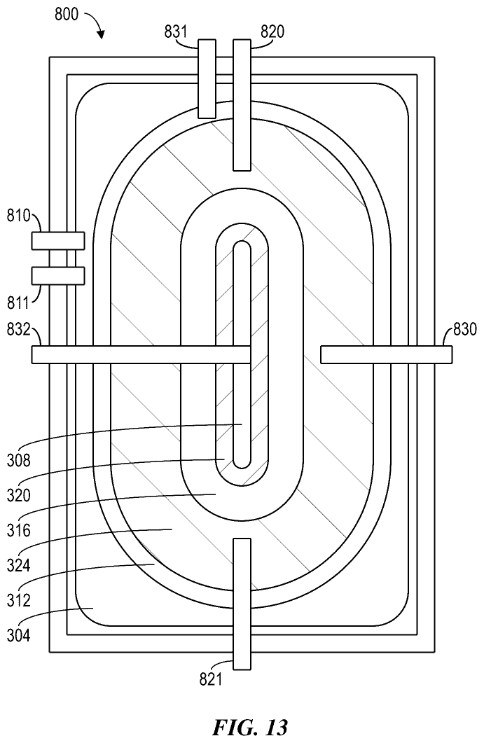

That is, the junction diode temperature sensor described above (e.g., with respect to FIGS. 10 and 11) may also be utilized in combination with the polysilicon temperature sensors described above (e.g., with respect to FIGS. 3-8). For example, FIG. 13 is a plan view of a portion of an IC apparatus 800 similar to the IC apparatus 300, 400, 420, 430, 440, 480 shown in FIGS. 3-8. That is, the IC apparatus 800 includes polysilicon members formed over a semiconductor substrate 804, the semiconductor substrate 304 including the above-described drain 308 and source 312, and the polysilicon members including the above-described drain field plate 320 and gate/field plate 324.

The IC apparatus 800 also includes two connections 810, 811 collectively connecting oppositely doped sides of the above-described junction diode to sensing circuitry (not shown, but similar to the above-described sensing circuitry 338 or 339 shown in FIGS. 3-8). The IC apparatus 800 also includes two connections 820, 821 connecting opposite ends of the gate/field plate 324 to the sensing circuitry. The sensing circuitry is configured to detect the temperature of the junction diode via the connections 810, 811 (e.g., when the transistor of the IC apparatus 800 is not active), and also to detect the temperature of the gate/field plate 324 via the connections 820, 821 (e.g., including when the transistor is active). FIG. 13 also depicts operational connections for the transistor of the IC apparatus 800, namely a gate drive connection 830 connected to the gate/field plate 324, a source connection 831 connected to the source 312, and a drain connection 832 connected to the drain 308.

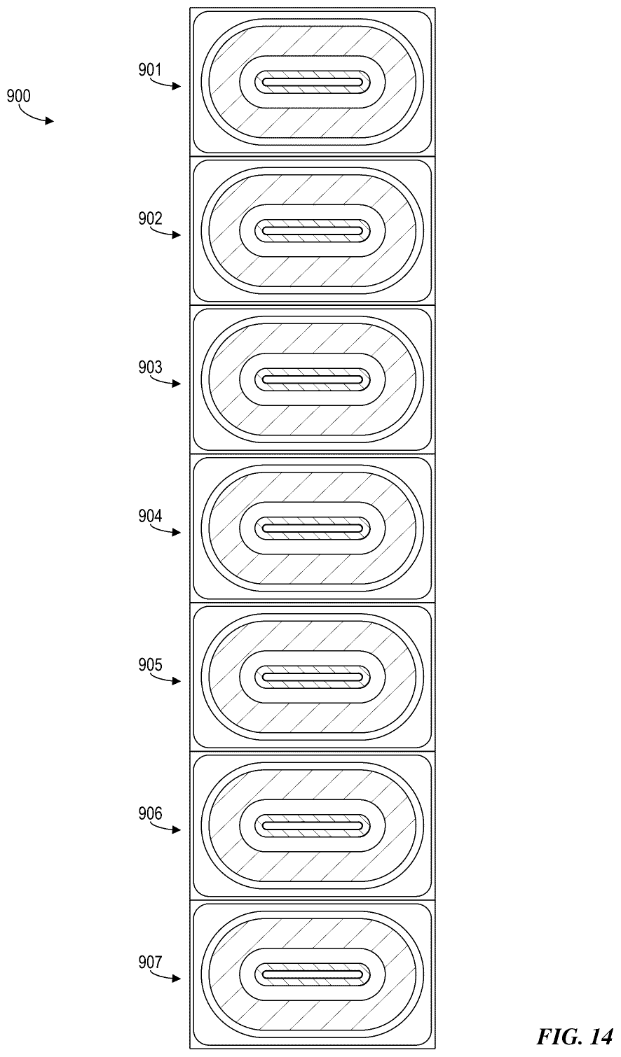

The temperature sensing introduced in the present disclosure may also be implemented as part of a larger array of transistor devices, such as in one finger of a multi-finger LDMOS device. For example, FIG. 14 is a plan view of a portion of an example implementation of an IC apparatus 900 according to one or more aspects of the present disclosure, the IC apparatus 900 comprising an array of transistor devices 901-907. Each transistor device 901-907 may be an instance of or otherwise be similar to one of the IC apparatus 300, 400, 420, 430, 440, 480 shown in FIGS. 3-8, including the respective connections connecting a temperature-sensed polysilicon member to sensing circuitry to detect the temperature of that polysilicon member.

Alternatively, different ones of the transistor devices 901-907 may be an instance of or otherwise similar to different ones of the IC apparatus 300, 400, 420, 430, 440, 480 shown in FIGS. 3-8, such that different ones of the transistor devices 901-907 are configured for the temperature sensing of different features of the transistor devices 901-907. For example, one or more of the transistor devices 901-907 may comprise connections for detecting the temperature of the source 312, whereas a different one or more of the transistor devices 901-907 may comprise connections for detecting the temperature of the drain 308, among other combinations of the implementations depicted in FIGS. 3-8.

However, one or more of the transistor devices 901-907 may not be configured (or at least not utilized) for the temperature sensing introduced herein. For example, in the implementation depicted in FIG. 14, the transistor device 904 may not have an integrated backgate and may have a deactivated gate (i.e., the gate 324 may be tied to the source 312 in one of FIGS. 3-8), such that the above-described junction diode may be utilized as a temperature sensing element. Alternatively, the gate and/or drain field plates may be utilized as temperature sensing elements. In either example, among others within the scope of the present disclosure, the temperature sensing performed utilizing just the transistor device 904 may be utilized to monitor the temperature of the entire array of transistor devices 901-907.

Although not shown in FIG. 14, the sensing circuitry for detecting the temperature of one or more features of one or more of the transistor devices 901-907 may be part of or separate from the chip comprising the transistor devices 901-907. Such sensing circuitry may be similar to the sensing circuitry 338 depicted in FIGS. 3-8. If more than one of the transistor devices 901-907 is utilized for temperature detection, the sensing circuitry may be a single circuit connected to each temperature-monitored transistor, or multiple sensing circuits each corresponding to one of the temperature-monitored transistors.

The temperature sensing introduced herein, whether for a single transistor device or a transistor array, may be implemented as a part of a circuit in which the temperature information is utilized in a feedback network. Such feedback may be utilized to optimize product performance, permitting real-time monitoring and optimization of the operating conditions. For example, the temperature information may be utilized to avoid thermal runaway of a transistor array, such as by controlling power distribution among the array transistors, especially in SOI and other technologies where a high degree of self-heating occurs and an efficient pathway for heat dissipation does not exist. Moreover, the temperature sensing introduced herein may utilize existing features of IC transistor devices without increasing device footprint or adding cost or complexity to the manufacturing process, including for high-voltage and/or high-power components where heat dissipation can be a critical concern.

The temperature sensing introduce herein may also be implemented utilizing features of a transistor device other than the polysilicon members or junction diodes. For example, the temperature sensing concepts introduced above may be applicable to or readily adaptable for detecting the temperature of the traces and/or vias of the interconnect structure, packaging components (lead frame, wires, etc.), and/or other components of a transistor IC.

In view of the entirety of the present disclosure, including the figures and the claims, a person having ordinary skill in the art will readily recognize that the present disclosure introduces an IC apparatus, comprising: a transistor constructed in a plurality of layers formed in or over a semiconductor substrate, wherein the transistor comprises a polysilicon member proximate a feature of the transistor; and circuitry comprising two connections to the polysilicon member, wherein the circuitry is configured to detect a temperature-dependent characteristic of the polysilicon member.

The temperature-dependent characteristic of the polysilicon member may be indicative of a temperature-related characteristic of the feature.

The temperature-related characteristic of the feature may be temperature of the feature.

The transistor may be a SOI device.

The transistor may be an LDMOS or DEMOS transistor.

The transistor may be a power transistor, e.g. having a drain drift region, or may be a MOS transistor lacking a drain drift region.

The feature may be a channel, source, and/or drain of the transistor.

The temperature-dependent characteristic may be resistivity.

The temperature-dependent characteristic may be current resulting from a voltage applied to the polysilicon member.

A portion of the polysilicon member may be non-silicided. The non-silicided portion of the polysilicon member may be implanted with a dopant that increases a temperature coefficient of resistivity of the non-silicided portion.

The circuitry may further comprise connections to oppositely doped portions of a junction diode formed in the transistor, and may be further configured to detect a temperature-dependent characteristic of the junction diode. The temperature-dependent characteristic of the junction diode may be temperature of the junction diode. The oppositely doped substrate portions may form a body and a source of the transistor.

The transistor may be one of an array of power transistors and the circuitry may be configured to detect a temperature characteristic of the power transistor array.

The present disclosure also introduces a method of manufacturing an IC apparatus, comprising: forming a transistor in a plurality of layers formed in or over a semiconductor substrate, including forming a polysilicon member proximate a feature of the transistor; and forming circuitry comprising two connections to the polysilicon member, wherein the circuitry is configured to detect a temperature-dependent characteristic of the polysilicon member.

The feature may be a channel, source, and/or drain of the transistor.

The temperature-dependent characteristic may be resistivity.

The temperature-dependent characteristic may be current resulting from a voltage applied to the polysilicon member.

Forming the transistor may comprise forming a silicide on a portion of the polysilicon member, thus defining: a silicided portion of the polysilicon member; and a non-silicided portion of the polysilicon member. Forming the polysilicon member may comprise implanting the non-silicided portion with a dopant such that a temperature coefficient of resistivity of the non-silicided portion is greater than a temperature coefficient of resistivity of the silicided portion.

Forming the circuitry may comprise forming two additional connections each to an oppositely doped portion of a junction diode formed in the transistor, such that the circuitry may be further configured to detect a temperature-dependent characteristic of the junction diode.

Forming the transistor may comprise forming an array of power transistors and the circuitry may be configured to detect a temperature characteristic of the power transistor array.

The present disclosure also introduces an IC apparatus, comprising: a transistor constructed in a plurality of layers formed in or over a semiconductor substrate, wherein the transistor comprises oppositely doped portions of the semiconductor substrate that form a junction diode; and circuitry comprising connections to the oppositely doped substrate portions, wherein the circuitry is configured to detect a temperature-dependent characteristic of the junction diode.

The temperature-dependent characteristic may be current resulting from a voltage applied across the junction diode.

The IC apparatus may further comprise a polysilicon member proximate a feature of the transistor, wherein the circuitry: further comprises two connections to the polysilicon member; and is configured to detect a temperature-dependent characteristic of the polysilicon member.

The present disclosure also introduces a method of manufacturing an IC apparatus, comprising: forming a transistor in a plurality of layers formed in or over a semiconductor substrate, including forming oppositely doped portions of the semiconductor substrate that collectively form a junction diode; and forming circuitry comprising connections to the oppositely doped substrate portions, wherein the circuitry is configured to detect a temperature-dependent characteristic of the junction diode.

The temperature-dependent characteristic may be current resulting from a voltage applied across the junction diode.

Forming the transistor may comprise forming a polysilicon member proximate a feature of the transistor, wherein the circuitry: further comprises two connections to the polysilicon member; and is configured to detect a temperature-dependent characteristic of the feature.

The foregoing outlines features of several embodiments so that a person having ordinary skill in the art may better understand the aspects of the present disclosure. A person having ordinary skill in the art will appreciate that they may readily use the present disclosure as a basis for designing or modifying other processes and structures for carrying out the same functions and/or achieving the same benefits of the embodiments introduced herein. A person having ordinary skill in the art will also realize that such equivalent constructions do not depart from the scope of the present disclosure, and that they may make various changes, substitutions and alterations herein without departing from the scope of the present disclosure.

The Abstract at the end of this disclosure is provided to comply with 37 C.F.R. § 1.72(b) to permit the reader to quickly ascertain the nature of the technical disclosure. It is submitted with the understanding that it will not be used to interpret or limit the scope or meaning of the claims.

What is claimed is:

1. An integrated circuit (IC), comprising:
a transistor constructed in a plurality of layers formed in or over a semiconductor substrate, wherein the transistor comprises a polysilicon member; and
circuitry comprising two connections to the polysilicon member, wherein the circuitry is configured to detect a resistance of the polysilicon member.

2. The IC of claim 1 wherein the resistance is temperature-dependent.

3. The IC of claim 1 wherein the transistor is a laterally-diffused metal-oxide semiconductor (LDMOS) transistor.

4. The IC of claim 1 wherein the transistor is a drain-extended metal-oxide semiconductor (DEMOS) transistor.

5. The IC of claim 1 wherein the polysilicon member is a gate electrode.

6. The IC of claim 1 wherein the polysilicon member is a field plate.

7. The IC apparatus of claim 1 wherein a portion of the polysilicon member is non-silicided.

8. The IC apparatus of claim 1 wherein:
the transistor is one of an array of transistors; and
the resistance of the polysilicon member is indicative of the temperature of the array of transistors.

9. A method of forming an integrated circuit, comprising:
forming a transistor in or over a semiconductor substrate, the transistor including a polysilicon member over the semiconductor substrate; and
forming circuitry comprising first and second connections to the polysilicon member, wherein the circuitry is configured to detect a resistance of the polysilicon member.

10. The method of claim 9 wherein the resistance is temperature-dependent.

11. The method of claim 9 wherein the transistor includes a drain drift region.

12. The method of claim 9 wherein the transistor is a laterally-diffused metal-oxide semiconductor (LDMOS) transistor.

13. The method of claim 9 wherein the polysilicon member is a gate electrode.

14. The method of claim 9 wherein the polysilicon member is a field plate.

15. The method of claim 9 wherein a portion of the polysilicon member is non-silicided.

16. The method of claim 9 wherein:
the transistor is one of an array of transistors; and
the resistance of the polysilicon member is indicative of the temperature of the array of transistors.

17. An integrated circuit (IC), comprising:
a transistor constructed in a plurality of layers formed in or over a semiconductor substrate, wherein the transistor comprises first and second oppositely doped portions of the semiconductor substrate that form a junction diode; and
circuitry comprising connections to the oppositely doped substrate portions, wherein the circuitry is configured to determine a current-voltage (I-V) characteristic of the junction diode.

18. The IC of claim 17 wherein the first and second doped portions include a body region and a source region.

19. The IC of claim 17 wherein a p⁺ contact to the first doped portion and an n⁺ contact to the second doped portion are isolated from each other at a top surface of the semiconductor substrate.

20. The IC of claim 17 wherein the p⁺ contact and the n⁺ contact are isolated by shallow trench isolation.
